(19) United States
(12) Patent Application Publication
(10) Pub. No.: US 2011/0205819 A1
(43) Pub. Date: Aug. 25, 2011

(54) REDUNDANCY DATA STORAGE CIRCUIT, REDUNDANCY DATA CONTROL METHOD AND REPAIR DETERMINATION CIRCUIT OF SEMICONDUCTOR MEMORY

(75) Inventors: Woo Hyun SEO, Icheon-si (KR); Kwang Myoung RHO, Icheon-si (KR)

(73) Assignee: HYNIX SEMICONDUCTOR INC., Icheon-si (KR)

(21) Appl. No.: 12/845,237

(22) Filed: Jul. 28, 2010

(30) Foreign Application Priority Data
Feb. 24, 2010 (KR) 10-2010-0016743

(51) Int. Cl. G11C 29/04

(52) U.S. Cl. 365/200; 365/171

(57) ABSTRACT

A redundancy data storage circuit of a semiconductor memory includes a memory cell array; a write driver configured to write redundancy data in the memory cell array in response to a test signal; and a sense amplifier configured to detect and output the redundancy data written in the memory cell array in response to a read signal.

### CROSS-REFERENCES TO RELATED APPLICATION

The present application claims priority under 35 U.S.C. §119(a) to Korean application number 10-2010-0016743, filed on Feb. 24, 2010, in the Korean Intellectual Property Office, which is incorporated herein by reference in its entirety as set forth in full.

### BACKGROUND

1. Technical Field

The present invention relates generally to a semiconductor memory, and more particularly to a redundancy data storage circuit, a redundancy data control method, and a repair determination circuit of a semiconductor memory.

2. Related Art

The circuit design of a semiconductor memory includes a provision to allow a repair operation, which will replace failed memory cells with redundancy cells.

That is, the semiconductor memory is designed with a repair determination circuit that stores the address data needing repair (hereinafter, “the repair address”), determines whether any address externally inputted corresponds to the stored repair address, and provides the determination result.

In a conventional repair determination circuit of a semiconductor memory, a plurality of address fuse sets are maintained, and a repair address is stored, for example, by physically removing the appropriate one of the metal fuses prior to packaging.

In order to physically remove the metal fuse, a process such as laser cutting or other similar process is required as a necessary step.

Consequently, the conventional technique presents problems, inter alia, in that no new repair address can be stored after packaging since the metal fuse has been physically cut.

### SUMMARY

A semiconductor memory capable of changing a repair address and storing a new repair address even after packaging is described herein.

Also, a semiconductor memory capable of obviating the need for a cutting process is described herein.

In one embodiment of the present invention, a redundancy data storage circuit of a semiconductor memory comprises a memory cell array; a write driver configured to write redundancy data in the memory cell array in response to a test signal; and a sense amplifier configured to detect and output the redundancy data written in the memory cell array in response to a read signal.

In another embodiment of the present invention, a redundancy data control method of a semiconductor memory having a memory cell array which is designated to store redundancy data comprises the steps of activating a test signal to allow the semiconductor memory to enter a test mode; writing the redundancy data in the memory cell array during an activation interval of the test signal; and outputting the redundancy data in response to a read signal during a deactivation interval of the test signal.

In another embodiment of the present invention, a repair determination circuit of a semiconductor memory comprises a redundancy data storage unit configured to store redundancy data inputted from an outside in response to a test signal, detect the stored redundancy data in response to a read signal, and output the detected redundancy data as redundancy addresses; a plurality of address comparison units configured to compare the redundancy addresses with column addresses and output comparison signals; and a determination unit configured to output a repair determination signal in response to the comparison signals.

### BRIEF DESCRIPTION OF THE DRAWINGS

Features, aspects, and embodiments are described in conjunction with the attached drawings, in which:

FIG. 1 is a block diagram illustrating a repair determination circuit of a semiconductor memory;

FIG. 2 is a circuit diagram of an address fuse set 120 shown in FIG. 1;

FIG. 3 is a circuit diagram of an address comparison unit 130 shown in FIG. 1;

FIG. 4 is a circuit diagram of a determination unit 140 shown in FIG. 1;

FIG. 5 is a block diagram illustrating a repair determination circuit of a semiconductor memory in accordance with an embodiment of the present invention;

FIG. 6 is a circuit diagram of a redundancy data storage unit shown in FIG. 5; and

FIG. 7 is a circuit diagram of a write driver shown in FIG. 6.

### DETAILED DESCRIPTION

Hereinafter, a redundancy data storage circuit, a redundancy data control method, and a repair determination circuit of a semiconductor memory according to embodiments of the present invention will be described below with reference to the accompanying drawings.

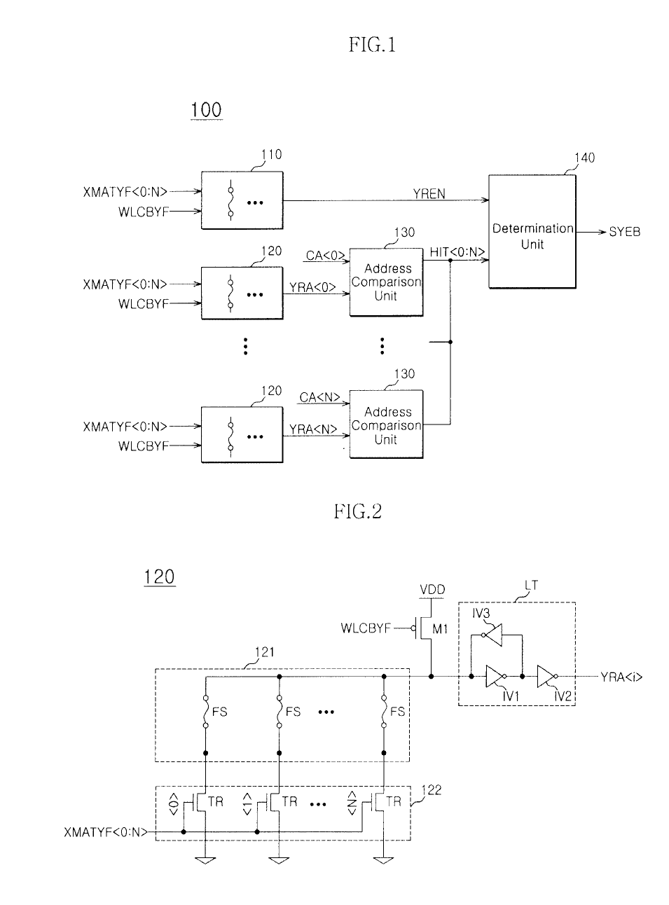

Referring to FIG. 1, a repair determination circuit 100 of a semiconductor memory includes an enable fuse set 110, a plurality of address fuse sets 120, a plurality of address comparison units 130, and a determination unit 140.

The enable fuse set 110 is configured to receive active signals XMATYF<0:N> and WLCBYF and output a fuse set enable signal YREN for informing whether or not to use a fuse setting circuit.

The active signals XMATYF<0:N> are signals which include information regarding activation of a unit cell array, that is, a cell mat divided in a row direction. The active signal WLCBYF is a signal which has information regarding activation of a word line. The active signal WLCBYF has a high level when the word line is activated and has a low level during a precharge operation.

The plurality of address fuse sets 120 are configured to receive the active signals XMATYF<0:N> and WLCBYF and output column redundancy addresses YRA<0:N>.

The plurality of address comparison units 130 are configured to compare the column redundancy addresses YRA<0:N> and column addresses CA<0:N> and output comparison signals HIT<0:N>.

The determination unit 140 is configured to output a repair determination signal SYEB according to the fuse set enable signal YREN and the comparison signals HIT<0:N>.

The enable fuse set 110 and the plurality of address fuse sets 120 can be configured in the same way.

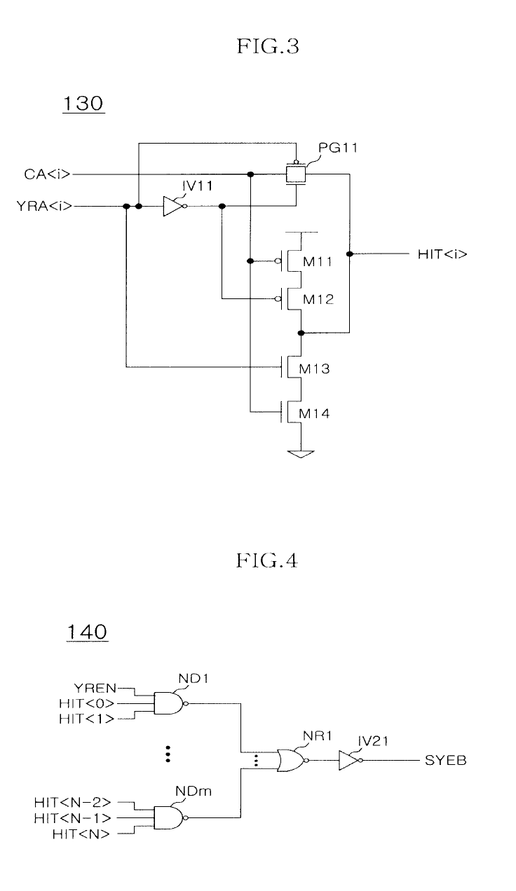

Referring to FIG. 2, the address fuse set 120 includes a fuse array 121, a transistor array 122, an initialization transistor M1, and a latch LT.

The fuse array 121 includes a plurality of fuses FS which correspond to repair addresses.

The transistor array 122 includes a plurality of transistors TR, and is configured to connect the fuse array 121 with a ground terminal according to the active signals XMATYF<0:N> and thereby activating the address fuse set 120.

The initialization transistor M1 initializes a column redundancy address YRA<i>according to the active signal WLCBYF.

During an interval in which the active signal WLCBYF has a high level, the column redundancy address YRA<i> can transit from an initial level, that is, a high level, to a low level according to a fuse cut state.

The latch LT maintains the level of the column redundancy address YRA<i>.

The plurality of address comparison units 130 can be configured in the same way.

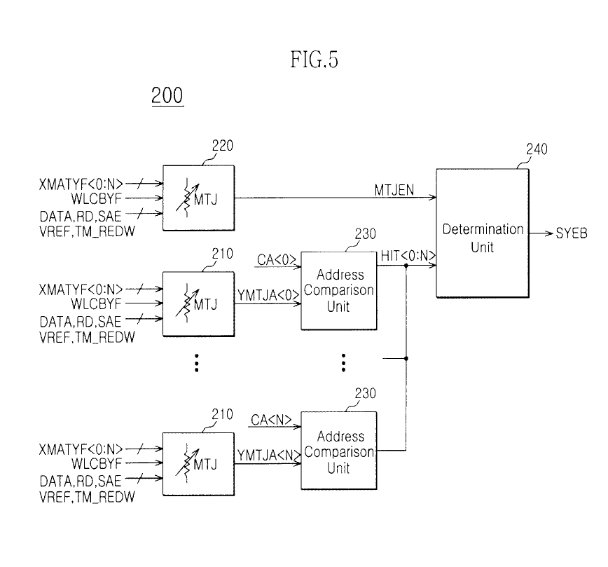

Referring to FIG. 3, the address comparison unit 130 includes an inverter IV11, a transmission gate PG11, and a plurality of transistors M11 through M14.

The address comparison unit 130 outputs the comparison signal HIT<i> to a high level when the column address CA<i> and the column redundancy address YRA<i> correspond to each other.

Referring to FIG. 4, the determination unit 140 includes a plurality of NAND gates ND1 through NDm, a NOR gate NR1, and an inverter IV21.

The determination unit 140 activates the repair determination signal SYEB to a low level and outputs the activated repair determination signal SYEB when the fuse set enable signal YREN and all the comparison signals HIT<0:N> have a high level.

An embodiment of the present invention is to store redundancy data in a memory cell which is configured using a nonvolatile memory element, more specifically a magnetic tunnel junction (MTJ), in place of a metal fuse used in the conventional art.

The magnetic tunnel junction is a memory element in which a magnetic direction is changed by applying an external stimulus such as current so that data can be stored. The magnetic tunnel junction can be used as the memory cell of a semiconductor memory.

Referring to FIG. 5, a repair determination circuit 200 of a semiconductor memory in accordance with an embodiment of the present invention includes a plurality of redundancy data storage units 210, a redundancy data activation unit 220, a plurality of address comparison units 230, and a determination unit 240.

The redundancy data storage units 210 are configured to store redundancy data DATA inputted from an outside in response to a test signal TM_REDW and active signals XMATYF<0:N>, and detect previously stored redundancy data DATA in response to a read signal RD and output redundancy addresses YMTJA<0:N>.

The test signal TM_REDW is a signal used to set a time at which writing of the redundancy data DATA is implemented.

The read signal RD is a signal which is generated according to a read command.

The active signals XMATYF<0:N> are signals which include information regarding activation of a unit cell array, that is, a cell mat divided in a row direction.

The redundancy data activation unit 220 is configured to store the redundancy data DATA inputted from the outside in response to the test signal TM_REDW and the active signals XMATYF<0:N>, and detect the previously stored redundancy data DATA in response to the read signal RD and output a redundancy activation signal MTJEN.

The plurality of address comparison units 230 are configured to compare the redundancy addresses YMTJA<0:N> and column addresses CA<0:N> and output comparison signals HIT<0:N>.

The plurality of address comparison units 230 are configured to activate the comparison signals HIT<0:N> when the redundancy addresses YMTJA<0:N> and the column addresses CA<0:N> to correspond to each other.

The plurality of address comparison units 230 can be configured in the same way as the address comparison units 130 shown in FIG. 3.

The determination unit 240 is configured to output a repair determination signal SYEB in response to the comparison signals HIT<0:N> and the redundancy activation signal MTJEN.

The determination unit 240 is configured to activate the repair determination signal SYEB to a low level when the comparison signals HIT<0:N> and the redundancy activation signal MTJEN are all activated to a high level.

The determination unit 240 can be configured in the same way as the determination unit 140 shown in FIG. 4.

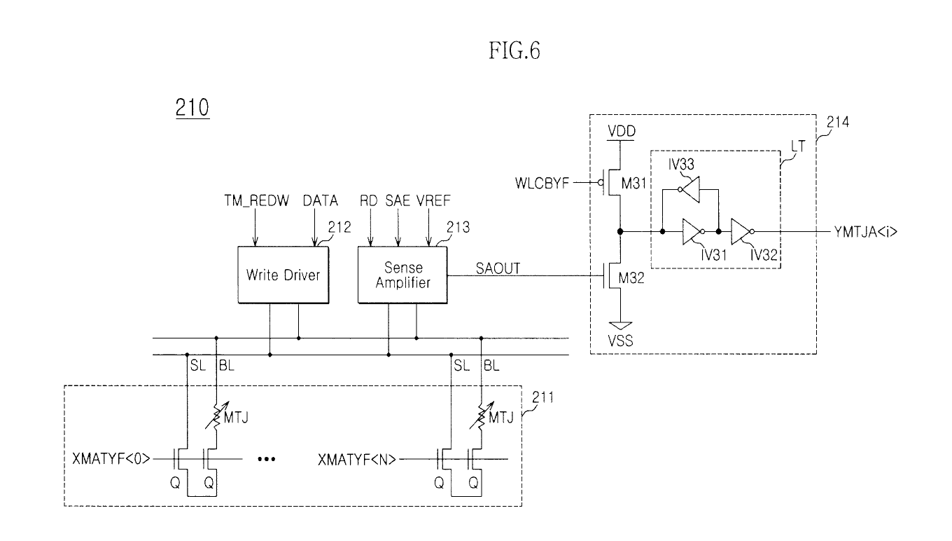

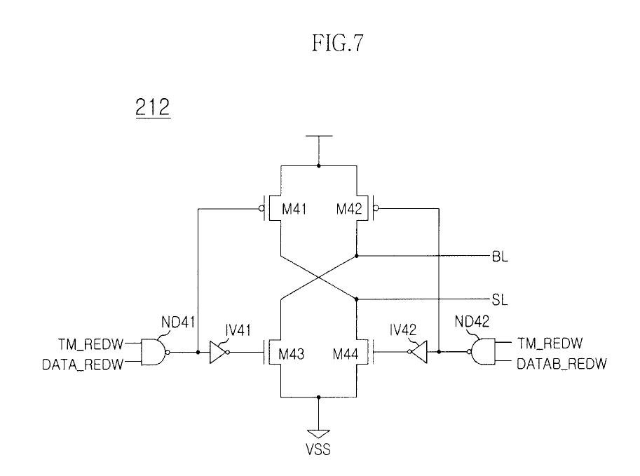

Referring to FIG. 6, the redundancy data storage unit 210 includes a memory cell array 211, a write driver 212, a sense amplifier 213, and an initialization section 214.

The memory cell array 211 has a plurality of memory cells each of which has a magnetic tunnel junction MTJ connected between a bit line BL and a source line SL and a pair of transistors Q. The active signals XMATYF<0:N> are inputted to pairs of transistors Q.

The plurality of memory cells of the memory cell array 211 are activated by the active signals XMATYF<0:N>. That is, they are changed to a state capable of writing/reading.

The magnetic tunnel junction MTJ is a nonvolatile memory element. By using the magnetic tunnel junction MTJ, it is not necessary to perform a refresh operation, which is essential in a semiconductor memory using a volatile memory element, for example, a DRAM, to conserve data.

The write driver 212 is configured to write the redundancy data DATA in the memory cell array 211 in response to the test signal is TM_REDW.

The sense amplifier 213 is configured to be activated in response to a sense amplifier enable signal SAE. The sense amplifier 213 is configured to detect and amplify the redundancy data DATA written in the memory cell array 211 by comparing the redundancy data DATA with a reference voltage VREF in response to the read signal RD, and output a detection signal SAOUT.

The semiconductor memory is provided with a general memory cell block, a write driver, and a sense amplifier which are configured to write and read general data, in addition to the memory cell array 211, the write driver 212, and the sense amplifier 213 shown in FIG. 6, which are configured to write and read the redundancy data DATA. Also, the semiconductor memory is provided with a redundancy memory cell block for replacing a general memory cell block.

In an embodiment of the present invention, a read signal, a sense amplifier enable signal and a reference voltage, which are used to drive the sense amplifier for reading the general data, can be used as the read signal RD, the sense amplifier enable signal SAE and the reference voltage VREF.

The initialization section 214 is configured to initialize a redundancy address YMTJA<i> in response an active signal WLCBYF and transit the level of the redundancy address YMTJA<i> in response to the detection signal SAOUT.

The active signal WLCBYF is a signal which has information regarding activation of a word line. The active signal WLCBYF has a high level when the word line is activated and has a low level during a precharge operation.

The initialization section 214 includes a driver which is comprised of a plurality of transistors M31, M32 and a latch LT which is comprised of a plurality of inverters IV31, IV32, IV33.

Referring to FIG. 7, the write driver 212 includes a plurality of transistors M41, M42, M43 M44, a plurality of inverters IV41, IV42, and a plurality of NAND gates ND41, ND42.

The write driver 212 receives the redundancy data DATA, that is, redundancy differential data DATA_REDW and DATAB_REDW during the activation interval of the test signal TM_REDW.

The write driver 212 is prevented from receiving the redundancy differential data DATA_REDW and DATAB_REDW during the deactivation interval of the test signal TM_REDW.

General data and the redundancy data DATA are inputted through the same input terminal. Accordingly, in an embodiment of the present invention, due to the fact that an input to the write driver 212 is controlled using the test signal TM_REDW, the general data inputted for a general data writing operation is prevented from being written in the memory cell array 211 of FIG. 6.

Operations of the repair determination circuit 200 of a semiconductor memory in accordance with an embodiment of the present invention, configured as mentioned above, will be described below.

According to an embodiment of the present invention, the address information, that is, the redundancy data DATA of a failed cell can be written in and read from the memory cell array 211 of FIG. 6 at any time not only before packaging but also after packaging.

In the conventional art, since metal fuses or others similar are used, it is impossible to reconnect the metal fuses after the metal fuses are removed through a process such as laser cutting before packaging. However, in an embodiment of the present invention, because the redundancy data DATA is stored in such a manner that data is written in a memory cell using a magnetic tunnel junction MJT, the redundancy data DATA can be rewritten even after packaging.

First, describing a method of writing the redundancy data DATA, the test signal TM_REDW is activated such that the semiconductor memory enters a test mode.

The redundancy data DATA and an address signal are inputted in the test mode.

The active signals XMATYF<0:N> are generated in response to the address signal.

A memory cell among the memory cells of the memory cell array 211 of FIG. 6 which corresponds to the active signals XMATYF<0:N> is activated.

Since the test signal TM_REDW is in an activated state, the write driver 212 of FIG. 7 writes the redundancy data DATA to the magnetic tunnel junction MJT of the activated memory cell.

After data writing is completed, the test signal TM_REDW is deactivated so that the test mode is finished.

In the state in which the test signal TM_REDW is deactivated, the write driver 212 cannot receive the general data. Accordingly, even when the general data is inputted through the same input terminal through which the redundancy data DATA is inputted, the redundancy data DATA written in the memory cell array 211 is maintained.

Next, describing a method of reading the written redundancy data DATA, as a general read command and an address are inputted, the read signal RD and the sense amplifier enable signal SAE are activated. Also, the active signals XMATYF<0:N> are generated according to the address signal.

A memory cell among the memory cells of the memory cell array 211 of FIG. 6 which corresponds to the active signals XMATYF<0:N> is activated.

The sense amplifier 213 detects and amplifies the redundancy data DATA stored in the activated memory cell according to the read signal RD and the sense amplifier enable signal SAE, and outputs the detection signal SAOUT.

Accordingly, the redundancy addresses YMTJA<0:N> are outputted from the plurality of redundancy data storage units 210, and the redundancy activation signal MTJEN is outputted from the redundancy data activation section 220.

The plurality of address comparison units 230 output the comparison signals HIT<0:N> to a high level when the redundancy is addresses YMTJA<0:N> and the column addresses CA<0:N> correspond to each other.

The determination unit 240 outputs the repair determination signal SYEB to a low level when all the comparison signals HIT<0:N> and the redundancy activation signal MTJEN have a high level.

As the repair determination signal SYEB has the low level, a general memory cell is replaced with a preset redundancy memory cell.

As is apparent from the above description, in an embodiment of the present invention, since changing and rewriting of a repair address are possible, repair of a failed cell is made possible even after packaging.

Also, in an embodiment of the present invention, since laser cutting is not necessary, a laser cutting equipment is not needed, and the efficiency of a repair task can be improved.

While one or more certain embodiments have been described above, it will be understood to those skilled in the art that the embodiment(s) described is by way of example only. Accordingly, the redundancy data storage circuit, the redundancy data control method, and the repair determination circuit of a semiconductor memory described herein should not be limited based on the described embodiment(s). Rather, the redundancy data storage circuit, the redundancy data control method and the repair determination circuit of a semiconductor memory described herein should only be limited in light of the claims that follow when taken in conjunction with the above description and accompanying drawings.

What is claimed is:

1. A redundancy data storage circuit of a semiconductor memory comprising:
a memory cell array;
a write driver configured to write redundancy data in the memory cell array in response to a test signal; and
a sense amplifier configured to detect and output the redundancy data written in the memory cell array in response to a read signal.

2. The redundancy data storage circuit according to claim 1, wherein the memory cell array comprises nonvolatile memory cells capable of being rewritten.

3. The redundancy data storage circuit according to claim 1, wherein the memory cell array includes memory cells, each of which is comprised of a magnetic tunnel junction (MTJ).

4. The redundancy data storage circuit according to claim 1, wherein the write driver is configured to receive the redundancy data during an interval in which the test signal is activated.

5. The redundancy data storage circuit according to claim 1, wherein the sense amplifier is configured to receive a read signal which is used to read data stored in a general memory cell block of a semiconductor memory as the read signal.

6. The redundancy data storage circuit according to claim 1, wherein the sense amplifier is configured to detect and output the redundancy data written in the memory cell array in response to a sense amplifier enable signal and the read signal.

7. A redundancy data control method of a semiconductor memory having a memory cell array which is designated to store redundancy data, comprising the steps of:
activating a test signal to allow the semiconductor memory to enter a test mode;
writing the redundancy data in the memory cell array during an activation interval of the test signal; and
outputting the redundancy data in response to a read signal during a deactivation interval of the test signal.

8. The redundancy data control method according to claim 7, wherein a read signal used to read data stored in a general memory cell block of the semiconductor memory is used as the read signal.

9. The redundancy data control method according to claim 7, wherein the deactivated test signal is used to prevent general data from being written in the memory cell array.

10. A repair determination circuit of a semiconductor memory, comprising:
a redundancy data storage unit configured to store redundancy data inputted from an outside in response to a test signal, detect the stored redundancy data in response to a read signal, and output the detected redundancy data as redundancy addresses;
a plurality of address comparison units configured to compare the redundancy addresses with column addresses and output comparison signals; and
a determination unit configured to output a repair determination signal in response to the comparison signals.

11. The repair determination circuit according to claim 10, wherein the redundancy data storage unit comprises:
a memory cell array having a plurality of memory cells each composed of a magnetic tunnel junction (MTJ);
a write driver configured to write the redundancy data in the memory cell array in response to the test signal;
a sense amplifier configured to detect the redundancy data written in the memory cell array in response to the read signal and output the detected redundancy data as the redundancy addresses.

12. The repair determination circuit according to claim 11, wherein the write driver is configured to receive the redundancy data during an activation interval of the test signal.

13. The repair determination circuit according to claim 11, wherein the sense amplifier is configured to detect and output the redundancy data written in the memory cell array in response to a sense amplifier enable signal and the read signal.

14. The repair determination circuit according to claim 13, wherein the sense amplifier is configured to receive, as the read signal and the sense amplifier enable signal, a read signal and a sense amplifier enable signal which are used to read data stored in a general memory cell block of the semiconductor memory.

15. The repair determination circuit according to claim 11, wherein the redundancy data storage unit further comprises:
an initialization section configured to initialize the redundancy addresses in response to active signals.

16. The repair determination circuit according to claim 10, wherein the address comparison units are configured to activate the comparison signals when the redundancy addresses and the respective column addresses correspond to each other.

17. The repair determination circuit according to claim 10, wherein the determination unit is configured to activate the repair determination signal when all the comparison signals are activated.

18. The repair determination circuit according to claim 10, wherein the determination unit is configured to activate the repair determination signal when all the comparison signals are activated and a redundancy activation signal is activated.

19. The repair determination circuit according to claim 18, further comprising:
a redundancy data activation unit configured to store the redundancy data in response to the test signal, detect the stored redundancy data in response to the read signal, and output the redundancy activation signal.
